(19) United States
(12) Patent Application Publication
(10) Pub. No.: US 2021/0367203 A1
(43) Pub. Date: Nov. 25, 2021

(54) DISPLAY PANEL AND MANUFACTURING METHOD THEREOF

(71) Applicant: WUHAN CHINA STAR OPTOELECTRONICS SEMICONDUCTOR DISPLAY TECHNOLOGY CO,, LTD., Wuhan (CN)

(72) Inventors: Xingliang PI, Wuhan (CN); Gaozhen WANG, Wuhan (CN)

(73) Assignee: WUHAN CHINA STAR OPTOELECTRONICS SEMICONDUCTOR DISPLAY TECHNOLOGY CO,, LTD., Wuhan (CN)

(21) Appl. No.: 16/609,219

(22) PCT Filed: Sep. 10, 2019
(86) PCT No.: PCT/CN2019/105105

§ 371 Date: Oct. 29, 2019

(30) Foreign Application Priority Data
May 17, 2019 (CN) 201910412917.5

(51) Int. Cl. H01L 51/52; H01L 51/56

(52) U.S. Cl. CPC H01L 51/5253; H01L 27/3244; H01L 51/56

(57) ABSTRACT

The present invention provides a display panel including a base and an encapsulation layer on the base. The encapsulation layer includes an organic layer and an inorganic layer disposed in a stack. The inorganic layer includes at least one flexible unit.

### FIELD OF INVENTION

The present invention relates to the field of display, and in particular to a display panel and a manufacturing method thereof.

### BACKGROUND OF INVENTION

In flat panel display technologies, organic light emitting diode (OLED) displays have many advantages such as being light and thin, active illumination, fast response times, large viewing angles, wide color gamut, high brightness, and low power consumption, and gradually become third-generation display technologies after liquid crystal displays.

In current OLED display panels, an encapsulation layer is usually composed of an organic film layer and an inorganic film layer. Due to disadvantages of large stress, brittleness, and bending resistance in the inorganic film layer, the current OLED display panels have a limited bending angle when bent and generate a large stress, which causing package failure.

Therefore, there is a need for a display panel to solve the above problems.

### SUMMARY OF INVENTION

The present invention provides a display panel and a manufacturing method thereof to solve the technical problem that an inorganic film layer in an encapsulation layer has a large stress when the display panel is bent.

In order to solve the above problems, the technical solution provided by the present invention is as follows.

The present invention provides a display panel comprising:

a base; and

an encapsulation layer on the base, comprises an organic layer and an inorganic layer disposed in a stack;

wherein the inorganic layer comprises at least one flexible unit.

In the display panel of the present invention, the encapsulation layer comprises a first inorganic layer on the base, a first organic layer on the first inorganic layer, and a second inorganic layer on the first organic layer;

wherein the first inorganic layer comprises at least one first groove; and

wherein the flexible unit is disposed in the first groove.

In the display panel of the present invention, the second inorganic layer comprises at least one second groove, and the flexible unit is disposed in the second groove.

In the display panel of the present invention, a concave surface of the first groove is a flat surface or a curved surface, and a concave surface of the second groove is a flat surface or a curved surface.

In the display panel of the present invention, a maximum depth of the first groove is greater than a maximum depth of the second groove.

In the display panel of the present invention, an area of a concave surface of the first groove is larger than an area of a concave surface of the second groove.

In the display panel of the present invention, the display panel comprises a curved area;

wherein the flexible unit is disposed on the inorganic layer corresponding to the curved area;

wherein the curved area comprises a first curved section, a second curved section, and a third curved section, and the second curved section is disposed between the first curved section and the third curved section; and

wherein the flexible unit has different density distributions in the first curved section, the second curved section, and the third curved section.

In the display panel of the present invention, a radius of curvature of the second curved section is less than a radius of curvature of the first curved section, and the radius of curvature of the second curved section is less than a radius of curvature of the third curved section; and

a density of the flexible unit in the second curved section is greater than a density of the flexible unit in the first curved section, and the density of the flexible unit in the second curved section is greater than a density of the flexible unit in the third curved section.

In the display panel of the present invention, a radius of curvature of the second curved section is less than a radius of curvature of the first curved section, and the radius of curvature of the second curved section is less than a radius of curvature of the third curved section;

a depth of the flexible unit is gradually increased in a direction from the first curved section to the second curved section; and

the depth of the flexible unit is gradually decreased in a direction from the second curved section to the third curved section.

In the display panel of the present invention, a radius of curvature of the second curved section is greater than a radius of curvature of the first curved section, and the radius of curvature of the second curved section is greater than a radius of curvature of the third curved section; and

a density of the flexible unit in the second curved section is less than a density of the flexible unit in the first curved section, and the density of the flexible unit in the second curved section is less than a density of the flexible unit in the third curved section.

In the display panel of the present invention, a radius of curvature of the second curved section is greater than a radius of curvature of the first curved section, and the radius of curvature of the second curved section is greater than a radius of curvature of the third curved section;

a depth of the flexible unit is gradually decreased in a direction from the first curved section to the second curved section; and

the depth of the flexible unit is gradually increased in a direction from the second curved section to the third curved section.

In the display panel of the present invention, the material of the flexible unit comprises one of photocurable adhesive or polyimide.

The present invention further provides a manufacturing method of a display panel, comprising:

providing a base, and forming a light emitting device layer on the base; and

forming an encapsulation layer on the light emitting device layer;

wherein the encapsulation layer comprises an organic layer and an inorganic layer disposed in a stack, and the inorganic layer comprises at least one flexible unit.

In the manufacturing method of the present invention, the step of forming an encapsulation layer on the light emitting device layer comprise:

forming a first inorganic layer on the light emitting device layer;

forming at least one first groove on the first inorganic layer;

filling a flexible unit in the first groove;

forming a first organic layer on the first inorganic layer; and

forming a second inorganic layer on the first organic layer;

wherein a concave surface of the first groove is a flat surface or a curved surface.

In the manufacturing method of the present invention, after forming the second inorganic layer on the first organic layer, further comprises:

forming a second groove on the second inorganic layer;

filling the flexible unit in the second groove; and

a concave surface of the second groove is a flat surface or a curved surface.

In the manufacturing method of the present invention, a maximum depth of the first groove is greater than a maximum depth of the second groove.

In the manufacturing method of the present invention, an area of the concave surface of the first groove is larger than an area of the concave surface of the second groove.

In the manufacturing method of the present invention, the display panel comprises a curved area, the flexible unit is disposed on the inorganic layer corresponding to the curved area;

the curved area comprises a first curved section, a second curved section, and a third curved section, and the second curved section is disposed between the first curved section and the third curved section; and

the flexible unit has different density distributions in the first curved section, the second curved section, and the third curved section.

In the manufacturing method of the present invention, a radius of curvature of the second curved section is less than a radius of curvature of the first curved section, and the radius of curvature of the second curved section is less than a radius of curvature of the third curved section; and

a density of the flexible unit in the second curved section is greater than a density of the flexible unit in the first curved section, and the density of the flexible unit in the second curved section is greater than a density of the flexible unit in the third curved section.

In the manufacturing method of the present invention, a radius of curvature of the second curved section is greater than a radius of curvature of the first curved section, and the radius of curvature of the second curved section is greater than a radius of curvature of the third curved section; and

a density of the flexible unit in the second curved section is less than a density of the flexible unit in the first curved section, and the density of the flexible unit in the second curved section is less than a density of the flexible unit in the third curved section.

Beneficial effects: the present invention provides a display panel and a manufacturing method thereof. The display panel comprises a base and an encapsulation layer on the base. The encapsulation layer comprises an organic layer and an inorganic layer disposed in a stack. The inorganic layer comprises at least one flexible unit. The present invention reduces an internal stress of the encapsulation layer by providing the flexible unit on the inorganic layer in the encapsulation layer, increases the bendable angle of the encapsulation layer, and improves the yield of the product package.

### DESCRIPTION OF DRAWINGS

In order to more clearly illustrate the embodiments or the technical solutions in the prior art, a brief introduction of the drawings used in the embodiments or the prior art description will be briefly described below. Obviously, the drawings in the following description are only some of the embodiments of the invention, and those skilled in the art can obtain other drawings according to the drawings without any creative work.

FIG. 1 is a first structural diagram of a display panel of the present invention.

FIG. 2 is a second structural diagram of the display panel of the present invention.

FIG. 3 is a third structural diagram of the display panel of the present invention.

FIG. 4 is a first structural diagram of a first inorganic layer of the display panel of the present invention.

FIG. 5 is a second structural diagram of the first inorganic layer of the display panel of the present invention.

FIG. 6 is a third structural diagram of the first inorganic layer of the display panel of the present invention.

FIG. 7 is a fourth structural diagram of the first inorganic layer of the display panel of the present invention.

FIG. 8 is a step diagram of a manufacturing method of the display panel of the present invention.

FIG. 9A to FIG. 9C are process steps of the manufacturing method of the display panel of the present invention.

### DETAILED DESCRIPTION OF PREFERRED EMBODIMENTS

The following embodiments refer to the accompanying figures for exemplifying specific implementable embodiments of the present invention in a suitable computing environment. It should be noted that the exemplary described embodiments are configured to describe and understand the present invention, but the present invention is not limited thereto. Directional terms, such as an upper side, a lower side, a front side, a back side, a left side, a right side, an inner side, an outer side, and a lateral side, mentioned in the present invention are only for reference. Therefore, the directional terms are used for describing and understanding rather than limiting the present invention. In the figures, units having similar structures are used for the same reference numbers.

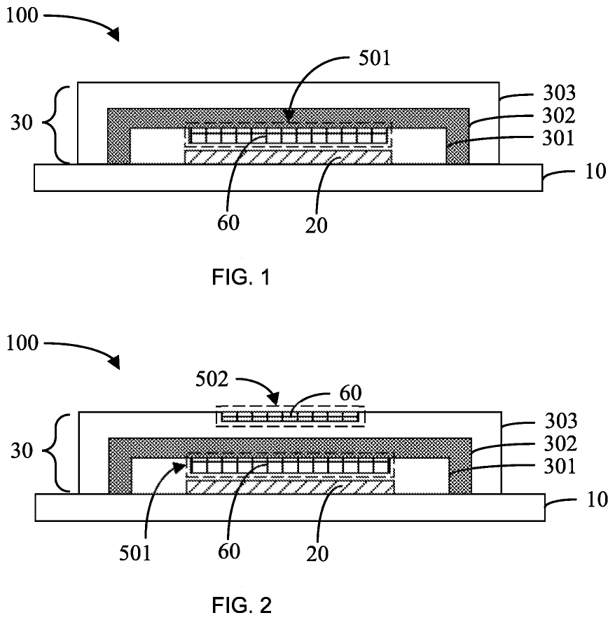

Please refer to FIG. 1. FIG. 1 is a first structural diagram of a display panel of the present invention.

The display panel 100 comprises a base 10, a light emitting device layer 20 on the base 10, and an encapsulation layer 30 on the light emitting device layer 20.

The base 10 comprises a substrate and a thin film transistor layer on the base.

In the embodiment, a raw material of the base may be one of a glass substrate, a quartz substrate, a resin substrate, and the like. When the substrate is a flexible substrate, the material of the flexible substrate may be polyimide (PI).

The thin film transistor layer comprises a plurality of thin film transistor units. The thin film transistor unit may be an etch barrier layer type, a back channel etch type or a top gate thin film transistor type, and the like, which is not limited in this embodiment.

This invention uses the top gate thin film transistor type as an example for illustration.

For example, the thin film transistor unit may comprise: a light shielding layer, a buffer layer, an active layer, a gate insulating layer, a gate electrode, an interlayer insulating layer, a source drain, a passivation layer, and a flat layer.

The light emitting device layer 20 may comprise an anode layer, a cathode layer, and a light emitting layer between the anode layer and the cathode layer. The specific structure of the light emitting device layer 20 is not discussed in detail in this invention.

The encapsulation layer 30 may be a thin film encapsulation layer, which is mainly used for blocking water and oxygen, preventing external water vapor from eroding the organic light emitting layer.

The encapsulation layer 30 comprises an organic layer and an inorganic layer disposed in a stack. The organic layer is usually disposed in the middle of the encapsulation layer 30, the inorganic layer is disposed on both sides of the encapsulation layer 30, and the organic layer is wrapped in the middle. The inorganic layer comprises at least one flexible unit 60.

Referring to FIG. 1, the encapsulation layer 30 comprises a first inorganic layer 301 on the base 10, a first organic layer 302 on the first inorganic layer 301, and a second inorganic layer 303 on the first organic layer 302.

The first inorganic layer 301 comprises at least one first groove 501, and the flexible unit 60 is disposed in the first groove 501.

In the embodiment, a concave surface of the first groove 501 may be a flat surface or a curved surface, etc., and is not specifically limited. The concave surface of the first groove 501 in FIG. 1 is a flat surface.

In the embodiment, the flexible unit 60 may also be disposed inside the inorganic layer.

Please refer to FIG. 2. FIG. 2 is a second structural diagram of the display panel of the present invention.

The second inorganic layer 303 may include at least one second groove 502, and the flexible unit 60 is disposed in the second groove 502.

In the embodiment, a concave surface of the second groove 502 may be a flat surface or a curved surface, etc., and is not specifically limited. The concave surface of the second groove 502 in FIG. 2 is a flat surface.

Since the display panel 100 of the present invention is a flexible display panel 100, a curved area 40 of the first inorganic layer 301 of the display panel 100 adjacent to the base 10 is larger than a curved area 40 of the second inorganic layer 303, such that when the flexible unit 60 is disposed in the package, an area of a flexible unit 60 of the first inorganic layer 301 is larger than an area of the flexible unit 60 of the second inorganic layer 303.

In the embodiment, a maximum depth of the first groove 501 is greater than a maximum depth of the second groove 502.

In the embodiment, the area of the concave surface of the first groove 501 is larger than the area of the concave surface of the second groove 502.

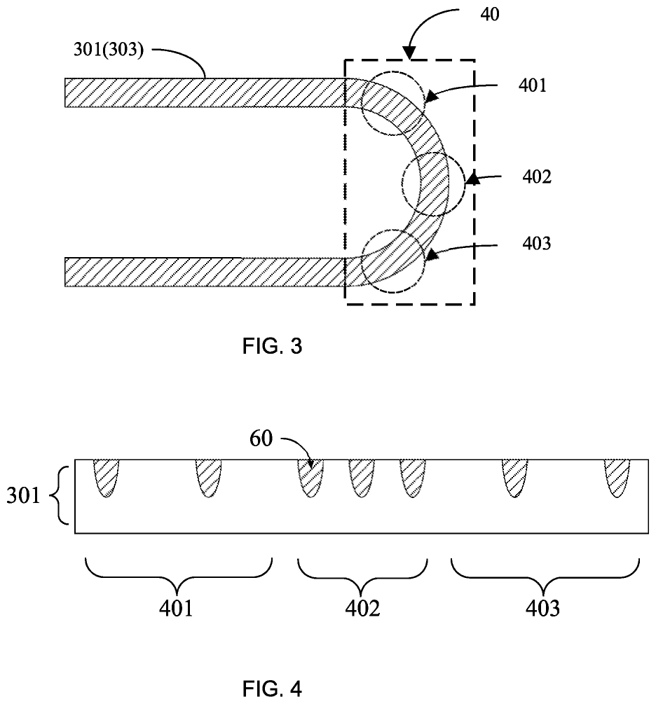

Please refer to FIG. 3. FIG. 3 is a third structure of the display panel of the present invention.

The display panel 100 comprises a curved area 40. The flexible unit 60 is disposed on the inorganic layer corresponding to the curved area 40.

The curved area 40 comprises a first curved section 401, a second curved section 402, and a third curved section 403, and the second curved section 402 is disposed between the first curved section 401 and the third curved section 403.

In the embodiment, the flexible unit 60 has different density distributions in the first curved section 401, the second curved section 402, and the third curved section 403.

The structure of the first inorganic layer 301 of the flexible unit 60 will be described below as an example.

Please refer to FIG. 4. FIG. 4 is a first structure of the first inorganic layer of the display panel of the present invention.

A radius of curvature of the second curved section 402 is less than a radius of curvature of the first curved section 401, and the radius of curvature of the second curved section 402 is less than a radius of curvature of the third curved section 403.

It can be seen from the mechanical analysis that the bending stress of the inorganic layer corresponding to the second curved section 402 is the largest, and the inorganic layer corresponding to the second curved section 402 is the most easily broken area of the display panel 100. A bending stress of the inorganic layer corresponding to the second curved section 402 is greater than a bending stress of the inorganic layer corresponding to the first curved section 401, and the bending stress of the inorganic layer corresponding to the second curved section 402 is greater than a bending stress of the inorganic layer corresponding to the third curved section 403.

In the embodiment, a density of the flexible unit 60 in the second curved section 402 is greater than a density of the flexible unit 60 in the first curved section 401, and the density of the flexible unit 60 in the second curved section 402 is greater than a density of the flexible unit 60 in the third curved section 403.

In the embodiment, the density of the flexible unit 60 gradually increases in a direction from the first curved section 401 to the second curved section 402. The density of the flexible unit 60 gradually decreases in a direction from the second curved section 402 to the third curved section 403.

The flexible unit 60 corresponding to an area where a bending stress is large is intensive, and the flexible unit 60 corresponding to an area where a bending stress is smaller is sparse. This reduces the bending stress of each area, avoids stress concentration, and improves the bending performance of the encapsulation layer 30 of the display panel 100.

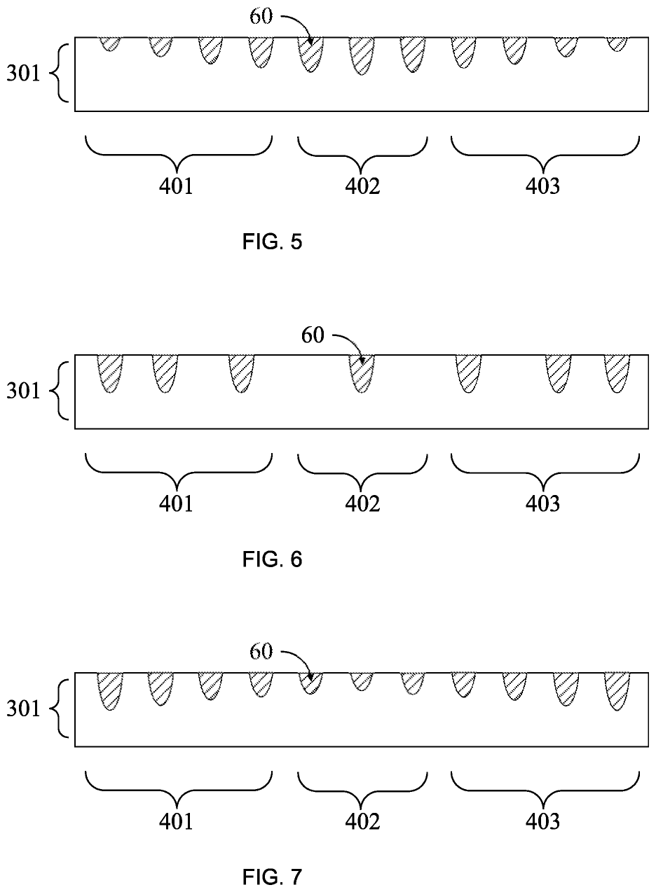

Please refer to FIG. 5. FIG. 5 is a second structure of the first inorganic layer of the display panel of the present invention.

A depth of the flexible unit 60 is gradually increased in a direction from the first curved section 401 to the second curved section 402. The depth of the flexible unit 60 is gradually decreased in a direction from the second curved section 402 to the third curved section 403.

The depth of the flexible unit 60 corresponding to an area where a bending stress is large is large. The depth of the flexible unit 60 corresponding to an area where a bending stress is small is small. This reduces the bending stress of each area, avoids stress concentration, and improves the bending performance of the encapsulation layer 30 of the display panel 100.

Please refer to FIG. 6. FIG. 6 is a third structure of the first inorganic layer of the display panel of the present invention.

A radius of curvature of the second curved section 402 is greater than a radius of curvature of the first curved section 401, and the radius of curvature of the second curved section 402 is greater than a radius of curvature of the third curved section 403.

It can be seen from the mechanical analysis that the inorganic layer corresponding to the first curved section 401 and the third curved section 403 receives a maximum bending stress, and the inorganic layer corresponding to the first curved section 401 and the third curved section 403 is the most easily broken area of the display panel 100. The bending stress of the inorganic layer corresponding to the second curved section 402 is smaller than the bending stress of the inorganic layer corresponding to the first curved section 401, and the bending stress of the inorganic layer corresponding to the second curved section 402 is smaller than the bending stress of the inorganic layer corresponding to the third curved section 403.

In the embodiment, a density of the flexible unit 60 in the second curved section 402 is less than a density of the flexible unit 60 in the first curved section 401, and the density of the flexible unit 60 in the second curved section 402 is less than a density of the flexible unit 60 in the third curved section 403.

In the embodiment, the density of the flexible unit 60 is gradually reduced in a direction from the first curved section 401 to the second curved section 402. The density of the flexible unit 60 gradually increases in a direction from the second curved section 402 to the third curved section 403.

The flexible unit 60 corresponding to an area where the bending stress is large is intensive, and the flexible unit 60 corresponding to an area where the bending stress is smaller is sparse. This reduces the bending stress of each area, avoids stress concentration, and improves the bending performance of the encapsulation layer 30 of the display panel 100.

Please refer to FIG. 7. FIG. 7 is a fourth structure of the first inorganic layer of the display panel of the present invention.

A depth of the flexible unit 60 is gradually decreased in a direction from the first curved section 401 to the second curved section 402. The depth of the flexible unit 60 is gradually increased in a direction from the second curved section 402 to the third curved section 403.

The depth of the flexible unit 60 corresponding to an area where a bending stress is large is large. The depth of the flexible unit 60 corresponding to an area where a bending stress is small is small. This reduces the bending stress of each area, avoids stress concentration, and improves the bending performance of the flexible substrate.

In the above embodiment, the material of the flexible unit 60 may comprise one of a photocurable adhesive or a polyimide.

The present invention reduces an internal stress of the encapsulation layer 30 by providing the flexible unit 60 on the inorganic layer in the encapsulation layer 30, increases bendable angles of the encapsulation layer 3, and improves the yield of the product package.

Please refer to FIG. 8. FIG. 8 is a step diagram of a manufacturing method of the display panel of the present invention.

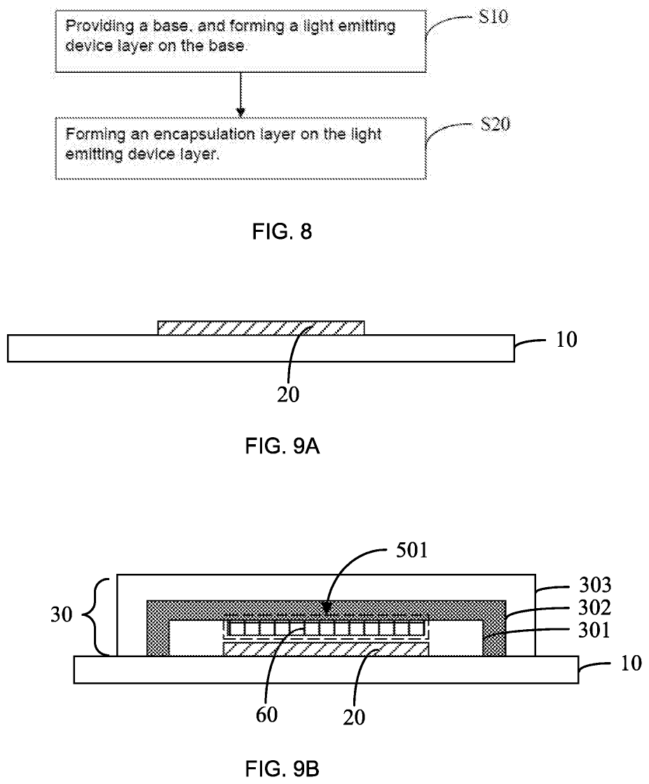

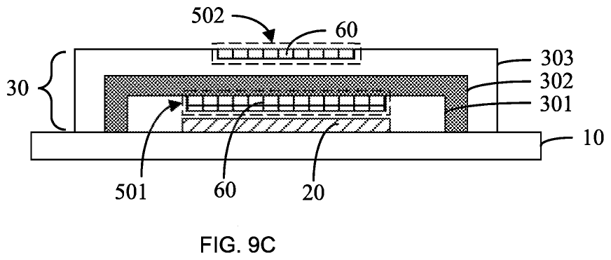

Please refer to FIG. 9A to FIG. 9C. FIG. 9A to FIG. 9C are process steps of the manufacturing method of the display panel of the present invention.

The manufacturing method comprises:

S10: Providing a base, and forming a light emitting device layer 20 on the base 10.

Please refer to FIG. 9A, in this step, the base 10 may include a substrate and a thin film transistor layer on the substrate.

In the embodiment, the material of the substrate may be one of a glass substrate, a quartz substrate, a resin substrate, and the like. When the substrate is a flexible substrate, the material of the flexible substrate may be polyimide (PI).

The thin film transistor layer comprises a plurality of thin film transistor cells. The thin film transistor unit may be an etch barrier layer type, a back channel etch type or a top gate thin film transistor type, and the like, which is not limited in this embodiment.

This invention uses the top gate thin film transistor type as an example for illustration.

For example, the thin film transistor unit may comprise: a light shielding layer, a buffer layer, an active layer, a gate insulating layer, a gate electrode, an interlayer insulating layer, a source drain, a passivation layer, and a flat layer.

The light emitting device layer 20 may comprise an anode layer, a cathode layer, and a light emitting layer between the anode layer and the cathode layer. The specific structure of the light emitting device layer 20 is not discussed in detail in this invention.

S20: Forming an encapsulation layer 30 on the light emitting device layer 20.

In this step, the encapsulation layer 30 comprises an organic layer and an inorganic layer disposed in a stack, and the inorganic layer comprises at least one flexible unit 60.

Please refer to FIG. 9B, step S20 specifically comprises:

S201: Forming a first inorganic layer 301 on the light emitting device layer 20;

S202: Forming at least one first groove 501 on the first inorganic layer 301;

S203: Filling a flexible unit 60 in the first groove 501;

S204: Forming a first organic layer 302 on the first inorganic layer 301; and

S205: Forming a second inorganic layer 303 on the first organic layer 302.

In this embodiment, a concave surface of the first groove 501 is a flat surface or a curved surface, and the like, and is not specifically limited.

Please refer to FIG. 9C, after forming the second inorganic layer 303 on the first organic layer 302, further comprises steps:

S206: Forming a second groove 502 on the second inorganic layer 303;

S207: Filling the flexible unit 60 in the second groove 502; and

S207: A concave surface of the second groove 502 is a flat surface or a curved surface.

In this embodiment, the concave surface of the second groove 502 is a flat surface or a curved surface, etc., and is not specifically limited.

Since the display panel 100 of the present invention is a flexible display panel 100, a curved area 40 of the first inorganic layer 301 of the display panel 100 adjacent to the base 10 is larger than a curved area 40 of the second inorganic layer 303, such that when the flexible unit 60 is disposed in the package, an area of a flexible unit 60 of the first inorganic layer 301 is larger than an area of the flexible unit 60 of the second inorganic layer 303.

In the embodiment, a maximum depth of the first groove 501 is greater than a maximum depth of the second groove 502.

In the embodiment, the area of the concave surface of the first groove 501 is larger than the area of the concave surface of the second groove 502.

Please refer to FIG. 3. The display panel 100 comprises a curved area 40. The flexible unit 60 is disposed on the inorganic layer corresponding to the curved area 40.

The curved area 40 comprises a first curved section 401, a second curved section 402, and a third curved section 403, and the second curved section 402 is disposed between the first curved section 401 and the third curved section 403.

Therefore, in step S202 and step S206, the density of the flexible unit 60 in the corresponding inorganic layer may be different according to different curved sections.

The structure of the flexible unit 60 in the first inorganic layer 301 will be described below as an example.

Please refer to FIG. 4, a radius of curvature of the second curved section 402 is less than a radius of curvature of the first curved section 401, and the radius of curvature of the second curved section 402 is less than a radius of curvature of the third curved section 403.

It can be seen from the mechanical analysis that the bending stress of the inorganic layer corresponding to the second curved section 402 is the largest, and the inorganic layer corresponding to the second curved section 402 is the most easily broken area of the display panel 100. A bending stress of the inorganic layer corresponding to the second curved section 402 is greater than a bending stress of the inorganic layer corresponding to the first curved section 401, and the bending stress of the inorganic layer corresponding to the second curved section 402 is greater than a bending stress of the inorganic layer corresponding to the third curved section 403.

In the embodiment, a density of the flexible unit 60 in the second curved section 402 is greater than a density of the flexible unit 60 in the first curved section 401, and the density of the flexible unit 60 in the second curved section 402 is greater than a density of the flexible unit 60 in the third curved section 403.

In the embodiment, the density of the flexible unit 60 gradually increases in a direction from the first curved section 401 to the second curved section 402. The density of the flexible unit 60 gradually decreases in a direction from the second curved section 402 to the third curved section 403.

The flexible unit 60 corresponding to an area where a bending stress is large is intensive, and the flexible unit 60 corresponding to an area where a bending stress is smaller is sparse. This reduces the bending stress of each area, avoids stress concentration, and improves the bending performance of the encapsulation layer 30 of the display panel 100.

Please refer to FIG. 5, a depth of the flexible unit 60 is gradually increased in a direction from the first curved section 401 to the second curved section 402. The depth of the flexible unit 60 is gradually decreased in a direction from the second curved section 402 to the third curved section 403.

The depth of the flexible unit 60 corresponding to an area where a bending stress is large is large. The depth of the flexible unit 60 corresponding to an area where a bending stress is small is small. This reduces the bending stress of each area, avoids stress concentration, and improves the bending performance of the encapsulation layer 30 of the display panel 100.

Please refer to FIG. 6, a radius of curvature of the second curved section 402 is greater than a radius of curvature of the first curved section 401, and the radius of curvature of the second curved section 402 is greater than a radius of curvature of the third curved section 403.

It can be seen from the mechanical analysis that the inorganic layer corresponding to the first curved section 401 and the third curved section 403 receives a maximum bending stress, and the inorganic layer corresponding to the first curved section 401 and the third curved section 403 is the most easily broken area of the display panel 100. The bending stress of the inorganic layer corresponding to the second curved section 402 is smaller than the bending stress of the inorganic layer corresponding to the first curved section 401, and the bending stress of the inorganic layer corresponding to the second curved section 402 is smaller than the bending stress of the inorganic layer corresponding to the third curved section 403.

In the embodiment, a density of the flexible unit 60 in the second curved section 402 is less than a density of the flexible unit 60 in the first curved section 401, and the density of the flexible unit 60 in the second curved section 402 is less than a density of the flexible unit 60 in the third curved section 403.

In the embodiment, the density of the flexible unit 60 is gradually reduced in a direction from the first curved section 401 to the second curved section 402. The density of the flexible unit 60 gradually increases in a direction from the second curved section 402 to the third curved section 403.

The flexible unit 60 corresponding to an area where the bending stress is large is denser. The flexible unit 60 corresponding to an area where the bending stress is smaller is less. This reduces the bending stress of each area, avoids stress concentration, and improves the bending performance of the encapsulation layer 30 of the display panel 100.

Please refer to FIG. 7, a depth of the flexible unit 60 is gradually decreased in a direction from the first curved section 401 to the second curved section 402. The depth of the flexible unit 60 is gradually increased in a direction from the second curved section 402 to the third curved section 403.

The depth of the flexible unit 60 corresponding to an area where a bending stress is large is large. The depth of the flexible unit 60 corresponding to an area where a bending stress is small is small. This reduces the bending stress of each area, avoids stress concentration, and improves the bending performance of the flexible substrate.

In the above embodiment, the material of the flexible unit 60 may comprise one of a photocurable adhesive or a polyimide.

According to another aspect of the present invention, a display module is further provided. The display module comprises the above display panel, and further comprises a touch layer, a polarizing layer and a cover layer disposed in sequence on the display panel.

According to another aspect of the present invention, an electronic device is further provided, and the electronic device comprises the display module. The electronic device comprises, but is not limited to, a mobile phone, a tablet, a computer display, a game machine, a television, a display screen, a wearable device, and other living appliances or household appliances having a display function.

The working principle of the display module and the working principle of the electronic device are similar to the working principle of the display panel. For the working principle of the display module and the working principle of the electronic device, reference may be made to the working principle of the display panel, which is not described herein.

The present invention provides a display panel and a manufacturing method thereof. The display panel comprises a base and an encapsulation layer on the base. The encapsulation layer comprises an organic layer and an inorganic layer disposed in a stack. The inorganic layer comprises at least one flexible unit. The present invention reduces an internal stress of the encapsulation layer by providing the flexible unit on the inorganic layer in the encapsulation layer, increases the bendable angle of the encapsulation layer, and improves the yield of the product package.

In summary, although the present invention has been disclosed above in the preferred embodiments, the above preferred embodiments are not intended to limit the present invention. A person skilled in the art can make various changes and refinements without departing from the spirit and scope of the present invention. Therefore, the scope of protection of the present invention is subject to the scope defined by the claims.

What is claimed is:

1. A display panel, comprising:
a base; and
an encapsulation layer on the base, comprising an organic layer and an inorganic layer disposed in a stack;
wherein the inorganic layer comprises at least one flexible unit.

2. The display panel as claimed in claim 1, wherein the encapsulation layer comprises a first inorganic layer on the base, a first organic layer on the first inorganic layer, and a second inorganic layer on the first organic layer;
wherein the first inorganic layer comprises at least one first groove; and
wherein the flexible unit is disposed in the first groove.

3. The display panel as claimed in claim 2, wherein the second inorganic layer comprises at least one second groove, and the flexible unit is disposed in the second groove.

4. The display panel as claimed in claim 3, wherein a concave surface of the first groove is a flat surface or a curved surface, and a concave surface of the second groove is a flat surface or a curved surface.

5. The display panel as claimed in claim 3, wherein a maximum depth of the first groove is greater than a maximum depth of the second groove.

6. The display panel as claimed in claim 3, wherein an area of a concave surface of the first groove is larger than an area of a concave surface of the second groove.

7. The display panel as claimed in claim 1, wherein the display panel comprises a curved area;
wherein the flexible unit is disposed on the inorganic layer corresponding to the curved area;
wherein the curved area comprises a first curved section, a second curved section, and a third curved section, and the second curved section is disposed between the first curved section and the third curved section; and
wherein the flexible unit has different density distributions in the first curved section, the second curved section, and the third curved section.

8. The display panel as claimed in claim 7, wherein a radius of curvature of the second curved section is less than a radius of curvature of the first curved section, and the radius of curvature of the second curved section is less than a radius of curvature of the third curved section; and
a density of the flexible unit in the second curved section is greater than a density of the flexible unit in the first curved section, and the density of the flexible unit in the second curved section is greater than a density of the flexible unit in the third curved section.

9. The display panel as claimed in claim 7, wherein a radius of curvature of the second curved section is less than a radius of curvature of the first curved section, and the radius of curvature of the second curved section is less than a radius of curvature of the third curved section;
a depth of the flexible unit is gradually increased in a direction from the first curved section to the second curved section; and
the depth of the flexible unit is gradually decreased in a direction from the second curved section to the third curved section.

10. The display panel as claimed in claim 7, wherein a radius of curvature of the second curved section is greater than a radius of curvature of the first curved section, and the radius of curvature of the second curved section is greater than a radius of curvature of the third curved section; and
a density of the flexible unit in the second curved section is less than a density of the flexible unit in the first curved section, and the density of the flexible unit in the second curved section is less than a density of the flexible unit in the third curved section.

11. The display panel as claimed in claim 7, wherein a radius of curvature of the second curved section is greater than a radius of curvature of the first curved section, and the radius of curvature of the second curved section is greater than a radius of curvature of the third curved section;
a depth of the flexible unit is gradually decreased in a direction from the first curved section to the second curved section; and
the depth of the flexible unit is gradually increased in a direction from the second curved section to the third curved section.

12. The display panel as claimed in claim 1, wherein the material of the flexible unit comprises one of photocurable adhesive or polyimide.

13. A manufacturing method of a display panel, comprising:
providing a base, and forming a light emitting device layer on the base; and
forming an encapsulation layer on the light emitting device layer;
wherein the encapsulation layer comprises an organic layer and an inorganic layer disposed in a stack, and the inorganic layer comprises at least one flexible unit.

14. The manufacturing method as claimed in claim 13, wherein the step of forming an encapsulation layer on the light emitting device layer comprise:
forming a first inorganic layer on the light emitting device layer;
forming at least one first groove on the first inorganic layer;
filling a flexible unit in the first groove;
forming a first organic layer on the first inorganic layer; and
forming a second inorganic layer on the first organic layer;
wherein a concave surface of the first groove is a flat surface or a curved surface.

15. The manufacturing method as claimed in claim 14, wherein after forming the second inorganic layer on the first organic layer, further comprises:
forming a second groove on the second inorganic layer;
filling the flexible unit in the second groove; and
a concave surface of the second groove is a flat surface or a curved surface.

16. The manufacturing method as claimed in claim 15, wherein a maximum depth of the first groove is greater than a maximum depth of the second groove.

17. The manufacturing method as claimed in claim 15, wherein an area of the concave surface of the first groove is larger than an area of the concave surface of the second groove.

18. The manufacturing method as claimed in claim 13, wherein the display panel comprises a curved area;
the flexible unit is disposed on the inorganic layer corresponding to the curved area;
the curved area comprises a first curved section, a second curved section, and a third curved section, and the second curved section is disposed between the first curved section and the third curved section; and
the flexible unit has different density distributions in the first curved section, the second curved section, and the third curved section.

19. The manufacturing method as claimed in claim 18, wherein a radius of curvature of the second curved section is less than a radius of curvature of the first curved section, and the radius of curvature of the second curved section is less than a radius of curvature of the third curved section; and
a density of the flexible unit in the second curved section is greater than a density of the flexible unit in the first curved section, and the density of the flexible unit in the second curved section is greater than a density of the flexible unit in the third curved section.

20. The manufacturing method as claimed in claim 18, wherein a radius of curvature of the second curved section is greater than a radius of curvature of the first curved section, and the radius of curvature of the second curved section is greater than a radius of curvature of the third curved section; and
a density of the flexible unit in the second curved section is less than a density of the flexible unit in the first curved section, and the density of the flexible unit in the second curved section is less than a density of the flexible unit in the third curved section.
